(19) United States
(12) Patent Application Publication
(10) Pub. No.: US 2025/0189555 A1
(43) Pub. Date: Jun. 12, 2025

(54) METHOD OF MANUFACTURING A PIEZOELECTRIC ACCELERATION SENSOR AND PIEZOELECTRIC ACCELERATION SENSOR OBTAINED BY THIS METHOD

(71) Applicant: Kistler Holding AG, Winterthur (CH)

(72) Inventors: Kim PFLUGER, Amherst, NY (US); Andrew Paul COOK, Williamsville, NY (US); Dan WOLF, Niagara Falls, NY (US)

(21) Appl. No.: 18/969,653

(22) Filed: Dec. 5, 2024

Related U.S. Application Data
(60) Provisional application No. 63/607,695, filed on Dec. 8, 2023.

(30) Foreign Application Priority Data
Jan. 19, 2024 (EP) 24152753.0

(51) Int. Cl. G01P 15/09; G01P 15/08; H05K 1/02

(52) U.S. Cl. CPC G01P 15/09; G01P 15/0802; H05K 1/028

(57) ABSTRACT

A method of manufacturing a piezoelectric acceleration sensor that includes a housing element containing a plurality of measuring elements, a flexible printed circuit board element and a connector element. Each measuring element measures an acceleration along a respective sensitive axis and generates electric charges proportionate for the measured acceleration. The flexible printed circuit board element hosts a plurality of IEPE, which amplify and convert electric charge from the measuring elements into an output voltage. The flexible printed circuit board element is introduced into the housing element and mechanically fixed to a body element inside the housing. The measuring elements are fixed to the body element. The measuring elements are electrically connected to the flexible printed circuit board element. The connector element is electrically connected with a connector section of the flexible printed circuit board and mounted on the housing element.

### FIELD OF THE INVENTION

The invention relates to a method of manufacturing a piezoelectric acceleration sensor and to a piezoelectric acceleration sensor obtained by this method.

### BACKGROUND OF THE INVENTION

An acceleration sensor is basically a force sensor with an attached mass. The mechanical quantity measured is a force which is proportional to the acceleration, according to Newton's second law of motion F=m*a. The mass m is usually called seismic mass. A piezoelectric acceleration sensor comprises piezoelectric material which creates electric charge when subjected to a force. The electric charge is proportional to the applied force and can be measured directly by means of electrodes. A piezoelectric acceleration sensor has the advantage of a fast response time of a few μsecs and is thus utilized to measure dynamic oscillations and vibrations on machines and structures.

Such a piezoelectric acceleration sensor is shown in applicant's commonly owned U.S. Pat. No. 6,397,677B1, which is hereby incorporated herein in its entirety for all purposes by this reference. The piezoelectric acceleration sensor comprises for each sensitive axis one piezoelectric measurement element which consists of a pair of spaced-apart accelerometer halves. For a triaxial piezoelectric acceleration sensor, three sensitive axes are mutually perpendicular to each other. Each accelerometer half comprises first and second plates from piezoelectric material and first and second seismic masses which are clamped by a bolt to a common post. By means of the post, the accelerometer halves are rigidly connected to a body. The accelerometer halves, the posts and the body are enclosed by a housing.

It is a general requirement to measure fast oscillations and vibrations, for which the piezoelectric acceleration sensor must have a high resonant frequency. And since the resonant frequency of the piezoelectric acceleration sensor is inversely proportional to its weight, the piezoelectric acceleration sensor should have a weight as small as possible.

The plates from piezoelectric material are made from shear type quartz with a nominal force sensitivity of 50 pC/N. To measure such a small electric charge largely without loss, a charge amplifier is built in the housing of the piezoelectric acceleration sensor. The charge amplifier converts the electric charge into an output voltage of typically ±5 V full scale, which can be easily processed further by standard measuring devices. For the conversion of electric charge from each piezoelectric measurement element, one charge amplifier is required. The charge amplifier must be provided with a supply voltage. Thus, the housing of a triaxial piezoelectric acceleration sensor comprises an electric feedthrough to exit the output voltage from three piezoelectric measurement elements and to enter the supply voltage for three charge amplifiers.

To further simplify the further processing of the output voltage, the piezoelectric acceleration sensor often comprises a transducer electronic data sheet (TEDS). TEDS is an IEEE 1451 standard and provides information about the piezoelectric acceleration sensor such as identification data, type designation, calibration data, etc. The TEDS can be read out by an evaluation unit via the electric feedthrough.

A triaxial piezoelectric acceleration sensor with integrated charge amplifier and TEDS is commercially distributed by the applicant and described as “Type 8763B” sensor in the datasheet 8763B_000-928e-05.22, which is herewith integrated by reference to applicant's commonly owned U.S. Pat. No. 9,841,434, which is hereby incorporated herein in its entirety for all purposes. The charge amplifier and the associated electronics of the “Type 8763B” sensor are called integrated electronics piezo-electric (IEPE). The “Type 8763B” sensor has one TEDS for each piezoelectric measurement element. The “Type 8763B” sensor has a hermetic and waterproof housing with a cubic shape and a small side length of 10.9 mm. The housing is made from titanium and has a light weight of 3.6 grams. The electric feedthrough consists of a four-pin connector.

The manufacturing of the “Type 8763B” sensor requires an assembly of three piezoelectric measurement elements, three IEPE, three TEDS and one printed circuit board within the small cubic housing. Strictly speaking, the three piezoelectric measurement elements are welded to the body inside the housing and the printed circuit board is glued to the body. Thereupon, for each sensitive axis, one IEPE and one TEDS are glued to the printed circuit board. Now, electrodes of each piezoelectric measurement element are electrically connected to the corresponding IEPE and to the housing. For each sensitive axis, the IEPE and the TEDS are electrically connected with each other. In addition, electrical connections must be made from the IEPE and the TEDS of each sensitive axis to the four-pin connector. This assembly is costly and error prone.

### OBJECTS AND SUMMARY OF THE INVENTION

A first object of the present invention is to provide a method of manufacturing a piezoelectric acceleration sensor which is in comparison with the “Type 8763B” sensor cost reduced and less error prone. The present invention also relates to a further object of a comparatively inexpensive piezoelectric acceleration sensor that can be produced by the method.

This object is achieved by the features of the method and sensor described hereinafter.

The present invention relates to a method of manufacturing a piezoelectric acceleration sensor, which piezoelectric acceleration sensor comprises a housing element, a plurality of measuring elements, a flexible printed circuit board element and a connector element, which housing element comprises an inner space and a body element in the inner space, which plurality of measuring elements measures an acceleration along a plurality of sensitive axes and creates a plurality of electric charges for the measured acceleration, which flexible printed circuit board element hosts a plurality of IEPE, each of the plurality of IEPE amplifies and converts electric charge from a related one of the plurality of measuring elements into an output voltage, which flexible printed circuit board element establishes a ground output voltage; the method comprising a step I of introducing the flexible printed circuit board element in the inner space of the housing element and of mechanically fixing the flexible printed circuit board element to the body element; a step II of introducing the plurality of measuring elements in the inner space of the housing element and of mechanically fixing the plurality of measuring elements to the body element; a step III of realizing first electrical connections of each of the plurality of measuring elements with a related one of a plurality of circuit board sections of the flexible printed circuit board element, the number of first electrical connections is equal to the number of the plurality of sensitive axes; and a step IV of realizing further electrical connections of the connector element with a connector section of the flexible printed circuit board element, the number of further electrical connections is equal to the number of the plurality of output voltages, and of mounting the electrically connected connector element on the housing element.

Present invention also relates to a piezoelectric acceleration sensor comprising a housing element with a body element, a plurality of measuring elements, a flexible printed circuit board element and a connector element, which housing element comprises an inner space and a body element in the inner space, which plurality of measuring elements measures an acceleration along a plurality of sensitive axes and creates a plurality of electric charges for the measured acceleration, which plurality of measuring elements is mechanically fixed to the body element, which flexible printed circuit board element hosts a plurality of IEPE, each of the plurality of IEPE amplifies and converts electric charge from a related one of the plurality of measuring elements into an output voltage, which flexible printed circuit board element establishes a ground output voltage, which flexible printed circuit board element is mechanically fixed to the body element; wherein the flexible printed circuit board element comprises a plurality of circuit board sections, each of the circuit board sections hosts one the plurality of IEPE, each of the plurality of measuring elements has a first electrical connection with a related one of the plurality of circuit board sections, the number of first electrical connections is equal to the number of the plurality of sensitive axes; wherein the flexible printed circuit board element comprises a connector section and the connector element has a further electrical connection with the connector section, the number of further electrical connections is equal to the number of the plurality of output voltages.

In comparison with the “Type 8763B” sensor, present invention drastically reduces the number of first electrical connection and of further electrical connections. For a triaxial piezoelectric acceleration sensor, the number of the plurality of sensitive axes is three and, thus, also the number of first electrical connections. And for a triaxial piezoelectric acceleration sensor, the number of the plurality of output voltages is four and, thus, also the number of further electrical connections. In total, a triaxial piezoelectric acceleration sensor according to the invention requires only seven electrical connections in the inner space of the housing element, whereas the “Type 8763B” sensor requires around three times as many electrical connections. Thus, not only the method of manufacturing a piezoelectric acceleration sensor is cost-effective and less error prone, also the manufactured piezoelectric acceleration sensor is less expensive.

Preferred embodiments of the invention are provided throughout the detailed description.

### BRIEF DESCRIPTION OF THE EXEMPLARY DRAWINGS

In the following, the invention is explained in more detail by way of example with reference to the figures, in which:

FIG. 1 shows a perspective view of a portion of a housing element 10 of a piezoelectric acceleration sensor 1;

FIG. 2 shows a cross-sectional view of a portion of a plurality of measuring elements 11x, 11y, 11z taken along each respective axis x, y, z in FIG. 6 before being mounted in the housing element 10 of the piezoelectric acceleration sensor 1 of FIG. 1;

FIG. 3 shows a top view of a portion of a flexible printed circuit board element 12 before being mounted in the housing element 10 of the piezoelectric acceleration sensor 1 of FIG. 1;

FIG. 4 shows a schematic view of a portion of an electric circuitry of the plurality of measuring elements 11x, 11y, 11z of FIG. 2, the flexible printed circuit board element 12 of FIG. 3 and a connector element 14;

FIG. 5 shows a perspective of a portion of the flexible printed circuit board element 12 of FIG. 3 after being mounted in the housing element 10 of the piezoelectric acceleration sensor 1 of FIG. 1;

FIG. 6 schematically shows a perspective view of a portion of the plurality of measuring elements 11x, 11y, 11z of FIG. 2 during mounting in the housing element 10 of the piezoelectric acceleration sensor 1 of FIG. 5;

FIG. 7 shows a perspective view of a portion of first electrical EC connections of the plurality of measuring elements 11x, 11y, 11z with the flexible printed circuit element 12 of FIG. 6;

FIG. 8 schematically shows a perspective view of portions of a plurality of cover elements 13x, 13y and of a connector element 14 before being mounted on the housing element 10 of the piezoelectric acceleration sensor 1 of FIG. 7;

FIG. 9 shows an enlarged view of a portion of further electrical connections FEC of the flexible printed circuit element 12 of FIG. 7 with the connector element 14 of FIG. 8; and

FIG. 10 shows a perspective view of a portion of the plurality of cover elements 13x, 13y and the connector element 14 of FIG. 8 after being mounted on the housing element 10 of the piezoelectric acceleration sensor 1 of FIG. 8.

Like reference numerals refer to like elements throughout. While the disclosure herein addresses the more general description of manufacturing an acceleration sensor that measures acceleration forces in three mutually orthogonal directions, the description applies equally well to acceleration sensors that only measure acceleration forces acting along a single axis or acting along two mutually orthogonal axes.

### DETAILED DESCRIPTION OF THE EXEMPLARY EMBODIMENTS OF THE INVENTION

### Housing Element 10

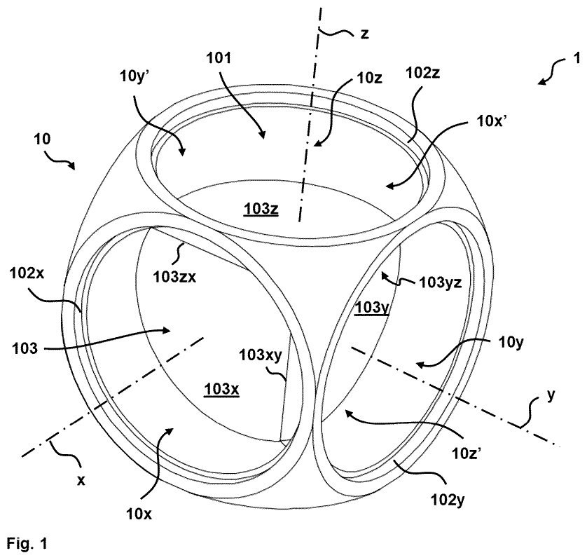

The piezoelectric acceleration sensor 1 comprises a housing element 10. FIG. 1 is a perspective view of a portion of the housing element 10.

The piezoelectric acceleration sensor 1 is arranged in a coordinate system with a plurality of axes x, y, z also referred to as the transverse axis x, the longitudinal axis y and the vertical axis z. Always two of the plurality of axes x, y, z are perpendicular to each other. Preferably, the number of the plurality of axes x, y, z is three mutually orthogonal axes.

The housing element 10 has the function to protect the piezoelectric acceleration sensor 1 from harmful environmental impacts such as contamination (dust, moisture, etc.) and from electrical and electromagnetic interference effects in the form of electromagnetic radiation. The housing element 10 is made of mechanically resistant material such as pure metals, titanium alloys, nickel alloys, cobalt alloys, iron alloys, etc.

Preferably, the housing element 10 has a cubic shape with six side faces 10x, 10x′, 10y, 10y′ 10z, 10z′, including:
A first transverse side face 10x and a second transverse side face 10x′ which is disposed spaced apart along the transverse axis x from the first transverse side face 10x. Each respective transverse side face 10x, 10x′ lies in a generally flat plane that is oriented normal to the transverse axis x.
A first longitudinal side face 10y and a second longitudinal side face 10y′ which is disposed spaced apart along the longitudinal axis y from the first longitudinal side face 10y. Each respective longitudinal side face 10y, 10y′ lies in a generally flat plane that is oriented normal to the longitudinal axis y.
A first vertical side face 10z and a second vertical side face 10z′ which is disposed spaced apart along the vertical axis z from the first vertical side face 10z. Each respective vertical side face 10z, 10z′ lies in a generally flat plane that is oriented normal to the vertical axis z.

Preferably, each of the six side faces 10x, 10x′, 10y, 10y′ 10z, 10z′ has a length of less/equal 2 cm. Preferably, the six side faces 10x, 10x′, 10y, 10y′ 10z, 10z′ are formed integrally as different regions of a unitary housing element 10.

The housing element 10 defines an inner space 101 which is delimited by the six side faces 10x, 10x′, 10y, 10y′ 10z, 10z′.

Preferably, the housing element 10 comprises a plurality of housing openings 102x, 102y, 102z that afford access from the exterior of the housing element 10 into the inner space 101 defined in the interior of the housing element 10. A transverse housing opening 102x is defined through the first transverse side face 10x and is configured to afford access into the inner space 101 from the direction of the transverse axis x. A longitudinal housing opening 102y is defined to through the first longitudinal side face 10y and is configured to afford access into the inner space 101 from the direction of the longitudinal axis y. A vertical housing opening 102z is defined to through the first vertical side face 10z and is configured to afford access into the inner space 101 from the direction of the vertical axis z.

Preferably, the second transverse side face 10x′, the second longitudinal side face 10y′ and the second vertical side face 10z′ are completely closed surfaces. As a result, the inner space 101 is inaccessible from outside the housing element 10 via the second transverse side face 10x′, the second longitudinal side face 10y′ and the second vertical side face 10z′.

The housing element 10 defines a body element 103 that desirably is formed integrally with the housing element 10 by machining the housing element 10 and body element 103 from a unitary workpiece. The body element 103 is configured to be arranged in the inner space 101. Preferably, the body element 103 is secured to and delimited by at least one of the second transverse side face 10x′, the second longitudinal side face 10y′ and the second vertical side face 10z′. Preferably, the body element 103 is formed integrally with at least one of the second transverse side face 10x′, the second longitudinal side face 10y′ and the second vertical side face 10z′.

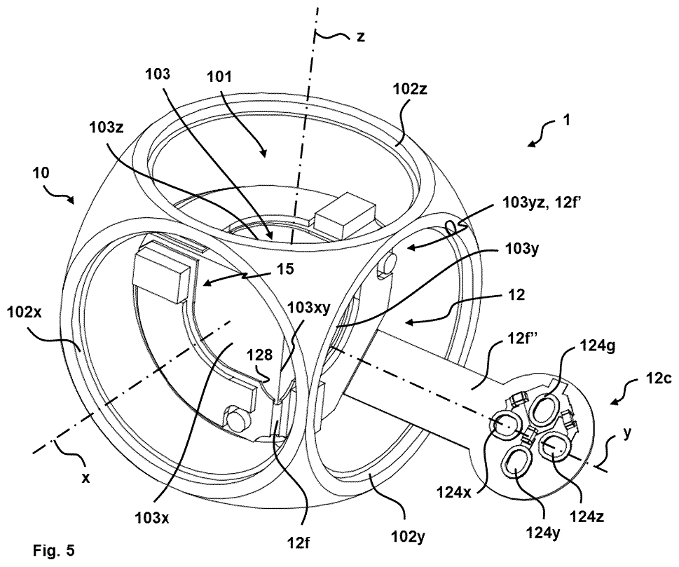

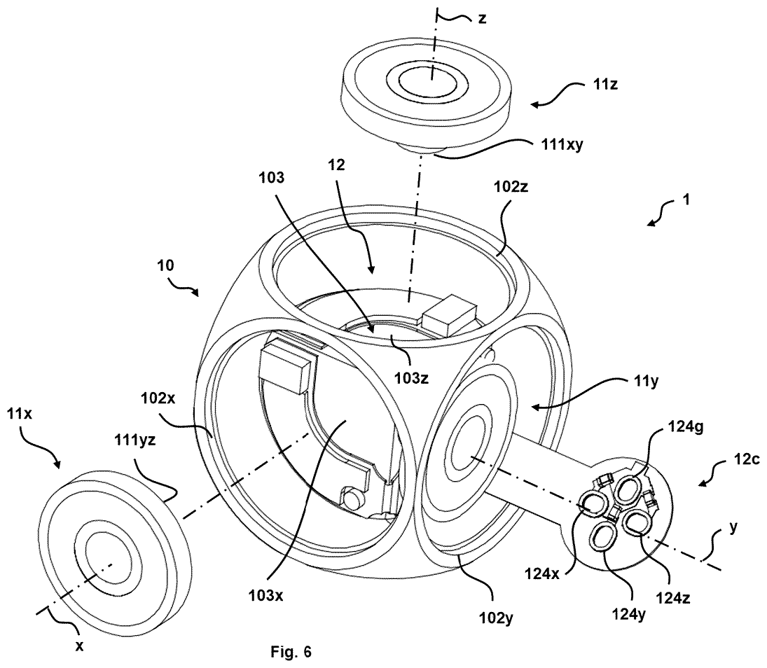

Preferably, as schematically shown in FIGS. 5 and 6, the body element 103 defines a plurality of surfaces 103x 103y, 103z that are disposed to face toward the inner space 101, including: A transverse surface 103x which is oriented normal to the transverse axis x. A longitudinal surface 103y which is oriented normal to the longitudinal axis y. A vertical surface 103z which is oriented normal to the vertical axis z.

Each of the respective plurality of surfaces 103x 103y, 103z is accessible from outside the housing element 10 via the respective one of the plurality of housing openings 102x, 102y, 102z. Each of the respective plurality of surfaces 103x 103y, 103z is substantially flat and lying in a plane that is normal to the respective axis x, y, z.

Two of the plurality of surfaces 103x 103y, 103z are directly adjacent and as schematically shown in FIG. 1 are separated from each other by a common edge 103xy, 103yz, 103zx, including: A first edge 103xy which separates the transverse surface 103x from the longitudinal surface 103y. A second edge 103yz which separates the longitudinal surface 103y from the vertical surface 103z. In the perspective view of FIG. 1, the second edge 103yz is hidden by other elements. A third edge 103zx which separates the vertical surface 103z from the transverse surface 103x.

### Measuring Element 11x, 11z, 11z

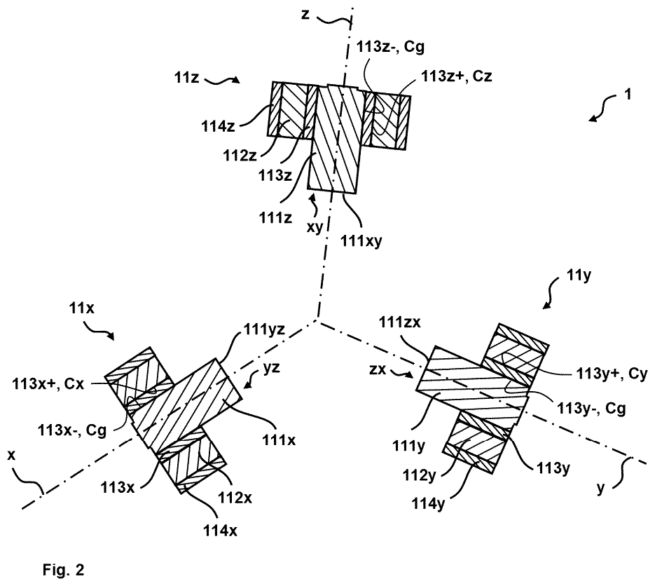

The piezoelectric acceleration sensor 1 comprises a plurality of measuring elements 11x, 11y, 11z. FIG. 2 is a cross-sectional view of a portion of the plurality of measuring elements 11x, 11z, 11z before being mounted in the housing element 10 of the piezoelectric acceleration sensor 1 of FIG. 1 as schematically shown in FIG. 6.

The plurality of measuring elements 11x, 11y, 11z has the function to create a plurality of electric charges Cx, Cy, Cz and ground charge Cg for an acceleration to be measured. Each of the plurality of electric charges Cx, Cy, Cz is proportional to the acceleration to be measured.

The plurality of measuring elements 11x, 11y, 11z has an identical construction. A transverse measuring element 11x measures an acceleration that acts along the transverse axis x and creates transverse electric charge Cx and ground charge Cg for the measured acceleration. The transverse axis x is also called sensitive axis x of the transverse measuring element 11x. The transverse measuring element 11x comprises a transverse post 111x, a transverse seismic mass 112x, a transverse piezoelectric element 113x and a transverse preloading element 114x.

A longitudinal measuring element 11y measures an acceleration that acts along the longitudinal axis y and creates longitudinal electric charge Cy and ground charge Cg for the measured acceleration. The longitudinal axis y is also called sensitive axis y of the longitudinal measuring element 11y. The longitudinal measuring element 11y comprises a longitudinal post 111y, a longitudinal seismic mass 112y, a longitudinal piezoelectric element 113y and a longitudinal preloading element 114y.

A vertical measuring element 11z measures an acceleration that acts along the vertical axis z and creates vertical electric charge Cz and ground charge Cg for the measured acceleration. The vertical axis z is also called sensitive axis z of the vertical measuring element 11z. The vertical measuring element 11z comprises a vertical post 111z, a vertical seismic mass 112z, a vertical piezoelectric element 113z and a vertical preloading element 114z.

Preferably, the piezoelectric acceleration sensor 1 is a triaxial piezoelectric acceleration sensor, and accordingly the number of the plurality of sensitive axes x, y, z of the plurality of measuring elements 11x, 11y, 11z is three. However, the disclosure herein applies equally well to acceleration sensors that only measure acceleration forces acting along a single axis (x or y or z) or acting along two mutually orthogonal axes (x and y, x and z or y and z).

As schematically shown in a cross-sectional view in FIG. 2, each of a respective one of the plurality of posts 111x, 111y, 111z mechanically supports each of a respective one of the seismic masses 112x, 112y, 112z, each of a respective one of the piezoelectric elements 113x, 113y, 113z and each of a respective one of the preloading elements 114x, 114y, 114x. Each of the plurality of posts 111x, 111y, 111z is made of mechanically resistant material such as pure metals, titanium alloys, nickel alloys, cobalt alloys, iron alloys, etc. Preferably, each of the plurality of posts 111x, 111y, 111z has a cylindrical shape. The transverse post 111x has a greater extension along the transverse axis x and a smaller extension in a transverse base plane yz, which is perpendicular to the transverse axis x. At one end along the transverse axis x, the transverse post 111x has a transverse post surface 111yz which lies in the transverse base plane yz. The longitudinal post 111y has a greater extension along the longitudinal axis y and a smaller extension in a longitudinal base plane zx, which is perpendicular to the longitudinal axis y. At one end along the longitudinal axis y, the longitudinal post 111y has a longitudinal post surface 111zx which lies in the longitudinal base plane zx. The vertical post 111z has a greater extension along the vertical axis z and a smaller extension in a vertical base plane xy, which is perpendicular to the vertical axis z. At one end along the vertical axis z, the vertical post 111z has a vertical post surface 111xy which lies in the vertical base plane xy.

Each of the plurality of seismic masses 112x, 112y, 112z is made of high-density material such as iridium, platinum, tungsten, gold, etc. Preferably, each of the plurality of seismic masses 112x, 112y, 112z has an annular shape, and includes: a transverse seismic mass 112x; a longitudinal seismic mass 112y; and a vertical seismic mass 112z.

Each of the plurality of piezoelectric elements 113x, 113y, 113z is made of piezoelectric material such as quartz, calcium gallo-germanate, langasite, gallium orthophosphate, piezoceramics, etc. Each of the plurality of piezoelectric elements 113x, 113y, 113z has a high sensitivity for the acceleration to be measured. Preferably, each of the plurality of piezoelectric elements 113x, 113y, 113z has an annular shape.

With respect to a radial direction, which is perpendicular to the transverse axis x, the transverse piezoelectric element 113x lies radially outside the transverse post 111x and radially inside the transverse seismic mass 112x. Under the effect of an acceleration, the transverse seismic mass 112x exerts a force which is proportional to its acceleration onto the transverse piezoelectric element 113x. The force is exerted in the aforementioned radial direction with respect to the transverse axis x. Preferably, the transverse piezoelectric element 113x exploits the piezoelectric shear effect and creates transverse electric charge Cx and ground charge Cg for the exerted force.

With respect to a radial direction, which is perpendicular to the longitudinal axis y, the longitudinal piezoelectric element 113y lies radially outside the longitudinal post 111y and radially inside the longitudinal seismic mass 112y. Under the effect of an acceleration, the longitudinal seismic mass 112y exerts a force which is proportional to its acceleration onto the longitudinal piezoelectric element 113y. The force is exerted in the aforementioned radial direction with respect to the longitudinal axis y. Preferably, the longitudinal piezoelectric element 113y exploits the piezoelectric shear effect and creates longitudinal electric charge Cy and ground charge Cg for the exerted force.

With respect to a radial direction, which is perpendicular to the vertical axis z, the vertical piezoelectric element 113z lies radially outside the vertical post 111z and radially inside the vertical seismic mass 112z. Under the effect of an acceleration, the vertical seismic mass 112z exerts a force which is proportional to its acceleration onto the vertical piezoelectric element 113z. The force is exerted in the aforementioned radial direction with respect to the vertical axis x. Preferably, the vertical piezoelectric element 113z exploits the piezoelectric shear effect and creates vertical electric charge Cz and ground charge Cg for the exerted force.

Each of the plurality of preloading elements 114x, 114y, 114z is made of mechanically resistant material such as pure metals, titanium alloys, nickel alloys, cobalt alloys, iron alloys, etc. Preferably, each of the plurality of preloading elements 114x, 114y, 114z has an annular shape.

A transverse preloading element 114x lies with respect to the radial direction, which is perpendicular to the transverse axis x, radially outside the transverse seismic mass 112x. The transverse preloading element 114x preloads the transverse seismic mass 112x and the transverse piezoelectric element 113x against the transverse post 111x. A longitudinal preloading element 114y lies with respect to the radial direction, which is perpendicular to the longitudinal axis y, radially outside the longitudinal seismic mass 112y. The longitudinal preloading element 114y preloads the longitudinal seismic mass 112y and the longitudinal piezoelectric element 113y against the longitudinal post 111y. A vertical preloading element 114z lies with respect to the radial direction, which is perpendicular to the vertical axis z, radially outside the vertical seismic mass 112z. The vertical preloading element 114z preloads the vertical seismic mass 112z and the vertical piezoelectric element 113z against the vertical post 111z.

As schematically shown in FIG. 2, each of the plurality of piezoelectric elements 113x, 113y, 113z defines a plurality of faces 113x+, 113y+, 113z+, 113x−, 113y−, 113z−, with the negative sign (−) designating the face where electrons predominate under pressure applied to the respective piezoelectric element 113 and the positive sign (+) designating the face where electrons are deficient under pressure applied to the respective piezoelectric element 113.

The transverse piezoelectric element 113x defines a transverse face 113x+, where transverse electric charge Cx is created for an acceleration. The transverse seismic mass 112x is applied on the transverse face 113x+and collects the transverse electric charge Cx. Due to the mechanical preloading, the transverse seismic mass 112x is electrically connected with the transverse preloading element 114x. The longitudinal piezoelectric element 113y defines a longitudinal face 113y+, where longitudinal electric charge Cy is created for an acceleration. The longitudinal seismic mass 112y is applied on the longitudinal face 113y+and collects the longitudinal electric charge Cy. Due to the mechanical preloading, the longitudinal seismic mass 112y is electrically connected with the longitudinal preloading element 114y. The vertical piezoelectric element 113z defines a vertical face 113z+, where vertical electric charge Cz is created for an acceleration. The vertical seismic mass 112z is applied on the vertical face 113z+and collects the vertical electric charge Cz. Due to the mechanical preloading, the vertical seismic mass 112z is electrically connected with the vertical preloading element 114z.

The transverse piezoelectric element 113x defines a ground transverse face 113x−, where ground electric charge Cg is created for the acceleration. The transverse post 111x is applied on the ground transverse face 113x− and collects the ground electric charge Cg. The longitudinal piezoelectric element 113y defines a ground longitudinal face 113y−, where ground electric charge Cg is created for the acceleration. The longitudinal post 111y is applied on the ground longitudinal face 113y− and collects the ground electric charge Cg. The vertical piezoelectric element 113z defines a ground vertical face 113z−, where ground electric charge Cg is created for the acceleration. The vertical post 111z is applied on the ground vertical face 113z− and collects the ground electric charge Cg.

### Flexible Printed Circuit Board Element 12

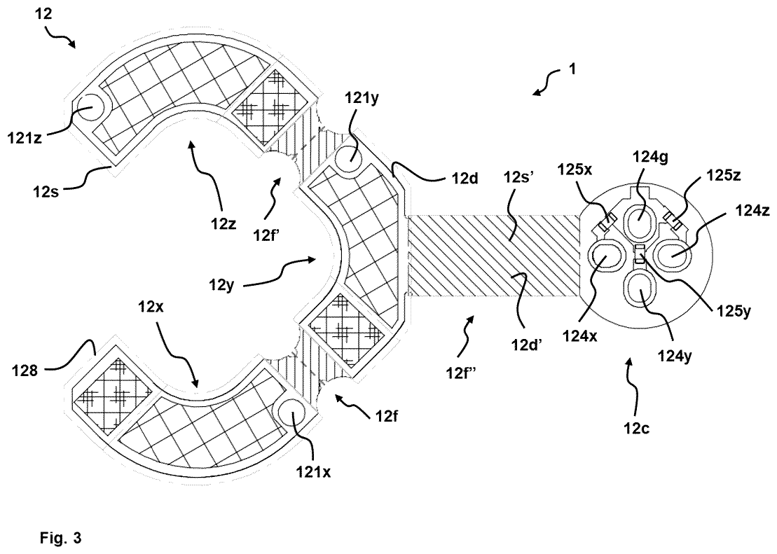

The piezoelectric acceleration sensor 1 comprises a flexible printed circuit board element 12. FIG. 3 is a top view of a portion of the flexible printed circuit board element 12 before being configuring into a pre-shaped printed circuit board wherein each of a plurality of circuit board sections is disposed to lie generally in a respective plane that is orthogonal to a respective plane in which lies each other of the plurality of circuit board sections and then mounted in the housing element 10 of the piezoelectric acceleration sensor 1 of FIG. 1.

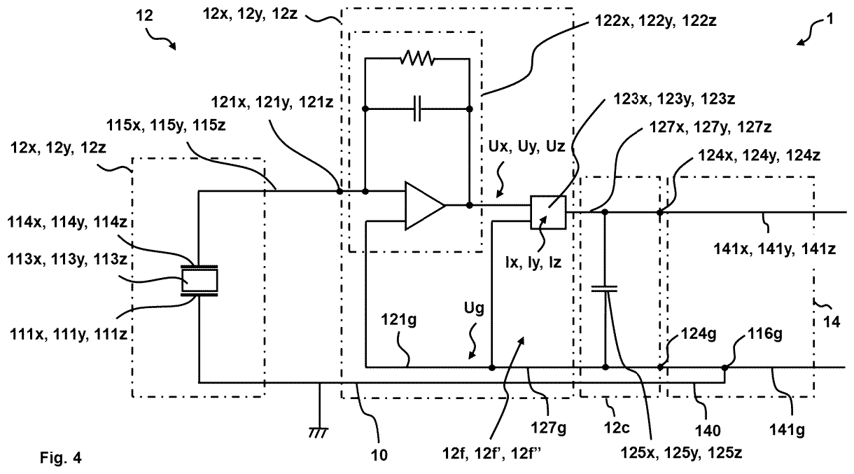

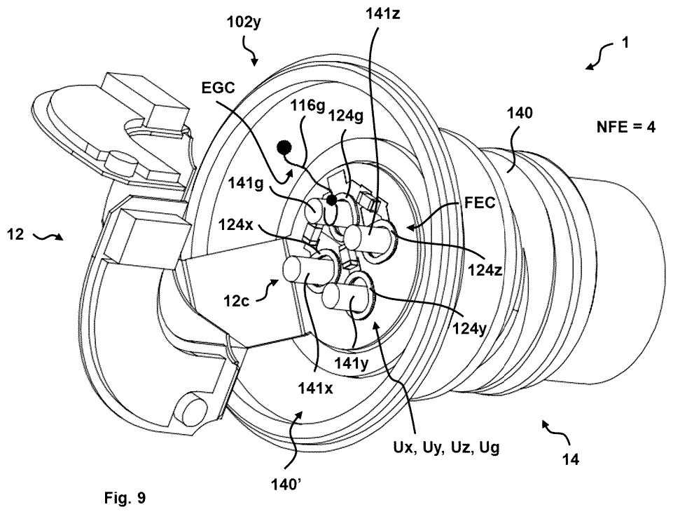

FIG. 4 is a schematic view of a portion of the electric circuitry of the plurality of measuring elements 11x, 11y, 11z of FIG. 2, the flexible printed circuit board element 12 of FIG. 3 and a connector element 14 of FIG. 9.

The flexible printed circuit board element 12 has the primary function to host a plurality of IEPE 122x, 122y, 122z schematically shown in FIG. 4. Each of the plurality of IEPE 122x, IEPE 122y, IEPE 122z has an identical construction. A transverse IEPE 122x amplifies and converts transverse electric charge Cx from the transverse seismic mass 112x of the transverse measuring element 11x into a transverse output voltage Ux. The transverse seismic mass 112x is electrically connected to an IEPE input of the transverse IEPE 122x. The transverse output voltage Ux is available at an IEPE output of the transverse IEPE 122x. The transverse IEPE 122x has a ground output. A longitudinal IEPE 122y amplifies and converts longitudinal electric charge Cy from the longitudinal seismic mass 112y of the longitudinal measuring element 11y into a longitudinal output voltage Uy. The longitudinal seismic mass 112y is electrically connected to an IEPE input of the longitudinal IEPE 122y. The longitudinal output voltage Uy is available at an IEPE output of the longitudinal IEPE 122y. The longitudinal IEPE 122y has a ground output. A vertical IEPE 122z amplifies and converts vertical electric charge Cz from the vertical seismic mass 112z of the vertical measuring element 11z into a vertical output voltage Uz. The vertical seismic mass 112z is electrically connected to an IEPE input of the vertical IEPE 122z. The vertical output voltage Uz is available at an IEPE output of the vertical IEPE 122z. The vertical IEPE 122z has a ground output. In the sense of the present invention, the adjective “related” has the meaning of “functionally dedicated”. The relationship goes in both directions. In the case at hand, each of the plurality of IEPE 122x, 122y, 122z is made for a related one of the plurality of measuring elements 11x, 11y, 11z and electric charge Cx, Cy, Cz from each of the plurality of measuring elements 11x, 11y, 11z is transmitted to a related one of the plurality of IEPE 122x, 122y, 122z.

The flexible printed circuit board element 12 has the secondary function to host a plurality of TEDS 123x, 123y, 123z. A transverse TEDS 123x with stored transverse information Ix about a related transverse measuring element 11x such as identification data, type designation, calibration data, etc. A longitudinal TEDS 123y with stored longitudinal information Iy about a related longitudinal measuring element 11y such as identification data, type designation, calibration data, etc. A vertical TEDS 123z with stored vertical information Iz about a related vertical measuring element 11z such as identification data, type designation, calibration data, etc.

Each of the plurality of TEDS 123x, TEDS 123y, TEDS 123z has an identical construction. Each of the plurality of TEDS 123x, TEDS 123y, TEDS 123z has a TEDS input, a TEDS output, a storage element and a ground output. Preferably, the IEPE output of each of the plurality of IEPE 122x, IEPE 122y, IEPE 122z is directly electrically connected with a TEDS input of a related one of the plurality of TEDS 123x, TEDS 123y, TEDS 123z. The information Ix, Iy, Iz stored in the storage element of each of the plurality of TEDS 123x, TEDS 123y, TEDS 123z as well as the output voltage Ux, Uy, Uz of each of the plurality of IEPE 122x, IEPE 122y, IEPE 122z are available at the TEDS output of each of the plurality of TEDS 123x, TEDS 123y, TEDS 123z.

The flexible printed circuit board element 12 comprises a plurality of discrete circuit board sections 12x, 12y, 12z, which are connected to each other. A transverse circuit board section 12x is configured to functionally serve the transverse measuring element 11x. The transverse circuit board section 12x comprises a transverse connection site 121x for a first electrical connection with the transverse measuring element 11x. The transverse circuit board section 12x comprises a ground connector 121g which is electrically connected with the ground output of the transverse IEPE 122x. The transverse circuit board section 12x comprises the transverse IEPE 122x with a charge amplifier and associated electronics. The transverse connection site 121x is electrically connected with the IEPE input of the transverse IEPE 122x. Optionally, the transverse circuit board section 12x comprises the transverse TEDS 123x. The transverse TEDS 123x is related with the transverse IEPE 122x. The ground output of the transverse TEDS 123x is electrically connected with the ground connector 121g.

A longitudinal circuit board section 12y is configured to functionally serve the longitudinal measuring element 11y. The longitudinal circuit board section 12y comprises a longitudinal connection site 121y for a first electrical connection with the longitudinal measuring element 11y. The longitudinal circuit board section 12y comprises a ground connector 121g which is electrically connected with the ground output of the longitudinal IEPE 122y. The longitudinal circuit board section 12y comprises the longitudinal IEPE 122y with a charge amplifier and associated electronics. The longitudinal connection site 121y is electrically connected with the IEPE input of the longitudinal IEPE 122y. Optionally, the longitudinal circuit board section 12x comprises the longitudinal TEDS 123y. The longitudinal TEDS 123y is related with the longitudinal IEPE 122y. The ground output of the longitudinal TEDS 123y is electrically connected with the ground connector 121g.

A vertical circuit board section 12z is configured to functionally serve the vertical measuring element 11z. The vertical circuit board section 12z comprises a vertical connection site 121z for a first electrical connection with the vertical measuring element 11z. The vertical circuit board section 12z comprises a ground connector 121g which is electrically connected with the ground output of the vertical IEPE 122z. The vertical circuit board section 12z comprises the vertical IEPE 122z with a charge amplifier and associated electronics. The vertical connection site 121z is electrically connected with the IEPE input of the vertical IEPE 122z. Optionally, the vertical circuit board section 12z comprises the vertical TEDS 123z. The vertical TEDS 123z is related with the vertical IEPE 122z. The ground output of the vertical TEDS 123z is electrically connected with the ground connector 121g.

The ground connector 121g establishes a ground output voltage Ug of the flexible printed circuit board element 12.

Each of the plurality of output voltages Ux, Uy, Uz, Ug is electrically conducted to an evaluation unit which is outside the housing element 10 of the piezoelectric acceleration sensor 1. The evaluation unit is not shown in the drawings. For a high accuracy of the acceleration measurement, the evaluation unit desirably is configured to differentiate each of the transverse output voltage Ux, the longitudinal output voltage Uy and the vertical output voltage Uz with the ground output voltage Ug. Preferably, the piezoelectric acceleration sensor 1 is a triaxial piezoelectric acceleration sensor and the number of the plurality of output voltages Ux, Uy, Uz, Ug is four.

The flexible printed circuit board element 12 comprises a connector section 12c, which is schematically shown in FIGS. 3 and 5-8 and related with the connector element 14 that is schematically shown in FIG. 4. The connector section 12c comprises a plurality of connection areas 124x, 124y, 124z, 124g. A transverse connection area 124x is configured to provide a further electrical connection with the connector element 14. A longitudinal connection area 124y is configured to provide a further electrical connection with the connector element 14. A vertical connection area 124z for a further electrical connection with the connector element 14. A ground connection area 124g is configured to provide a further electrical connection with the connector element 14.

Preferably, as schematically shown in FIG. 4, the connector section 12c comprises a plurality of electro-static discharge protectors 125x, 125y, 125z, which are capacitors which increase the capacitance at the connection areas 124x, 124y, 124z, 124g. A transverse electro-static discharge protector 125x is electrically connected in parallel with the transverse connection area 124x and the ground connection area 124g. A longitudinal electro-static discharge protector 125y is electrically connected in parallel with the longitudinal connection area 124y and the ground connection area 124g. A vertical electro-static discharge protector 125z is electrically connected in parallel with the vertical connection area 124z and the ground connection area 124g.

As schematically shown in FIG. 3, each of the circuit board sections 12x, 12y, 12z and the connector section 12c comprises a circuit board substrate 12s of electrically insulating material such as fiber-reinforced polymer with fibers from glass, carbon, aramid, etc. and polymers from epoxy, vinyl ester, polyester thermosetting plastic, etc. The circuit board substrate 12s has a two-dimensional substrate surface 12d that defines the top surface of the circuit board substrate 12s. Preferably, the circuit board substrate 12s has an elevated stiffness and has a flexural strength of greater/equal 300 MPa.

The flexible printed circuit board element 12 comprises a plurality of flexible sections 12f, 12f′, 12f″ that link different sections of the circuit board element 12. A first flexible section 12f flexibly links the transverse circuit board section 12x with the longitudinal circuit board section 12y. A second flexible section 12f′ flexibly links the vertical circuit board section 12z with the longitudinal circuit board section 12y. A third flexible section 12f″ flexibly links the longitudinal circuit board section 12y with the connector section 12c.

As schematically shown in FIG. 3, each flexible section 12f, 12f′, 12f″ comprises a flexible substrate 12s′ of electrically insulating material such as polyimide, polytetrafluoroethylene, polyether ether ketone, etc. The flexible substrate 12s′ has a two-dimensional flexible substrate surface 12d′. Preferably, the flexible substrate 12s′ is easy to bend and has a flexural strength of less/equal 200 MPa. None of the flexible sections 12f, 12f′, 12f″ overlays any of the respective circuit board sections 12x, 12y, 12 z, 12c.

Each of the flexible sections 12f, 12f′, 12f″ comprises at least two electric conductors 127x, 127y, 127z, 127g. A transverse electric conductor 127x electrically connects the IEPE output of the transverse IEPE 122x with the transverse connection area 124x such that the transverse output voltage Ux is electrically conducted to the transverse connection area 124x. A longitudinal electric conductor 127y electrically connects the IEPE output of the longitudinal IEPE 122y with the longitudinal connection area 124y, such that the longitudinal output voltage Uy is electrically conducted to the longitudinal connection area 124y. A vertical electric conductor 127z electrically connects the IEPE output of the vertical IEPE 122z with the vertical connection area 124z such that the vertical output voltage Uz is electrically conducted to the vertical connection area 124z. A ground electric conductor 127g electrically connects the ground connector 121g of each of the plurality of circuit board sections 12x, 12y, 12z with the ground connection area 124g such that the ground output voltage Ug is electrically conducted to the ground connection area 124g.

Each of the electric conductors 127x, 127y, 127z, 127g is made of electrically conductive material such as copper, copper alloys, etc.

As schematically shown in FIG. 3 for example, each of the flexible printed circuit board element 12 comprises a substantially flat underside 128. Each of the circuit board sections 12x, 12y, 12z comprises a separate section of the underside 128 indicated by the chain-dashed outline thereof. Preferably, the underside 128 expands over each of the plurality of circuit board sections 12x, 12y, 12z. However, the underside 128 does not extend beneath any of the flexible sections 12f, 12f′, 12f″.

### Cover Elements 13x, 13z

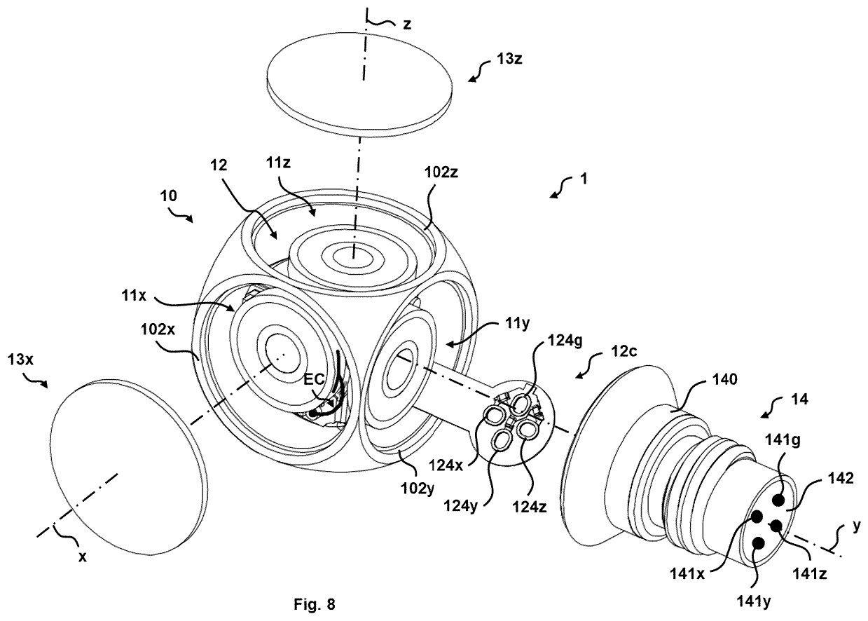

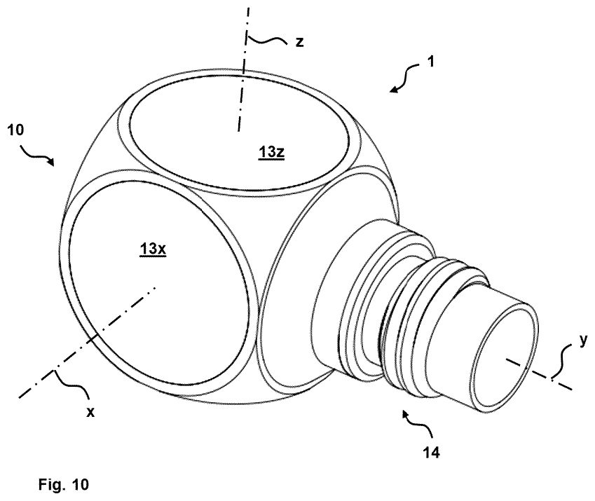

The piezoelectric acceleration sensor 1 comprises a plurality of cover elements 13x, 13z. The FIGS. 8 and 10 show portions of the plurality of cover elements 13x, 13z in disassembled perspective view and an assembled perspective view, respectively.

The plurality of cover elements 13x, 13z include a transverse cover element 13x and a vertical cover element 13z. The transverse cover element 13x is configured to perform the function of hermetically closing the transverse housing opening 102x of the housing 10. The vertical cover element 13z is configured to perform the function of hermetically closing the vertical housing opening 102z of the housing 10.

The cover elements 13x, 13z are made of mechanically resistant material such as pure metals, titanium alloys, nickel alloys, cobalt alloys, iron alloys, etc. The cover elements 13x, 13z have an identical construction.

### Connector Element 14

The piezoelectric acceleration sensor 1 comprises a connector element 14. The FIGS. 8 to 10 show portions of the connector element 14 in a disassembled perspective view, a partially assembled perspective view and a fully assembled perspective view, respectively. As schematically shown in FIG. 8, the connector element 14 comprises a connector housing element 140, a plurality of electric connector conductors 141x, 141y, 141z, 141g and an electric insulation element 142.

The connector housing element 140 is configured to perform the function of mechanically fixing the plurality of electric connector conductors 141x, 141y, 141z, 141g and the electric insulation element 142 in the longitudinal housing opening 102y of the housing element 10 and to hermetically close the longitudinal housing opening 102y of the housing element 10.

The connector housing element 140 is made of mechanically resistant material such as pure metals, titanium alloys, nickel alloys, cobalt alloys, iron alloys, etc.

As schematically shown in FIG. 9, the connector housing element 140 defines therein a connector housing through hole 140′ that is configured for receiving an insertion of the electric insulation element 142 and a mechanical fixation of the inserted electric insulation element 142. Preferably, this mechanic fixation is obtained by material bonding such as soldering, adhesive bonding, etc.

As schematically shown in FIG. 9, the plurality of electric connector conductors 141x, 141y, 141z, 141g are configured and disposed to electrically conduct the plurality of output voltages Ux, Uy, Uz, Ug from the inner space 101 to the evaluation unit which is outside the housing element 10. The plurality of electric connector conductors 141x, 141y, 141z, 141g are made of electrically conductive material such as copper, copper alloys, etc. A transverse electric connector conductor 141x is disposed for electrically conducting the transverse output voltage Ux out of the inner space 101. A longitudinal electric connector conductor 141y is disposed for electrically conducting the longitudinal output voltage Uy out of the inner space 101. A vertical electric connector conductor 141z is disposed for electrically conducting the vertical output voltage Uz out of the inner space 101. A ground electric connector conductor 141g is disposed for electrically conducting the ground output voltage Ug out of the inner space 101.

The electric insulation element 142 has the function to mechanically fix the plurality of electric connector conductors 141x, 141y, 141z, 141g and to electrically insulate the plurality of electric connector conductors 141x, 141y, 141z, 141g from each other and from the connector housing element 140. The electric insulation element 142 is made of electrically insulating material such as Al₂O₃, ceramics, Al₂O₃ ceramics, etc.

Preferably, the mechanical fixation of the inserted plurality of electric connector conductors 141x, 141y, 141z, 141g with the electric insulation element 142 is obtained by material bonding such as soldering, adhesive bonding, etc.

### Step I

FIG. 5 is a perspective view of a portion of the flexible printed circuit board element 12 of FIG. 3 after being mounted on the body element 103 in the housing element 10 of the piezoelectric acceleration sensor of FIG. 1.

In step I, the flexible printed circuit board element 12 is configured from the planar configuration shown in FIG. 3 into a pre-shaped printed circuit board 12 as shown in FIG. 5 for example. In the view shown in FIG. 3, the discrete sections 12x, 12y, 12z, 12c, 12f, 12f′, 12″ are disposed to line in the same plane. FIG. 5 presents a perspective view that shows each of the plurality of circuit board sections 12x, 12y, 12z disposed to lie generally in a respective different plane that is orthogonal to a respective plane in which lies each other of the plurality of circuit board sections 12x, 12y, 12z. This is done by folding the flexible sections 12f, 12f′, and 12f″ of the flexible circuit board element 12 shown in FIG. 3 at a right angle. The pre-shaped flexible printed circuit board element 12 is introduced into the inner space 101 of the housing element 10 via one of the plurality of housing openings 102x, 102y, 102z in the housing element 10.

The so introduced pre-shaped flexible printed circuit board element 12 is mechanically fixed to the body element 103. The mechanical fixation is obtained by material bonding such as welding, soldering, adhesive bonding, etc. The mechanical fixation is realized via a fixation means 15 schematically shown in FIG. 5. Preferably, the mechanical fixation is obtained by adhesive bonding, and the fixation means 15 desirably includes an adhesive such as epoxy, polyurethane, cyanoacrylate, methyl methacrylate, etc. The adhesive can be cured to obtain the mechanical end strength of the adhesive bonding. Preferably, the fixation means 15 is electrically conducting.

Prior to the introduction of the pre-shaped flexible printed circuit board element 12 into the inner space 101, the fixation means 15 is applied on the plurality of surfaces 103x, 103y, 103z of the body element 103.

In step I, the introduced flexible printed circuit board element 12 is mechanically contacted with the applied fixation means 15. This mechanical contact is realized via the underside 128 of the flexible printed circuit board element 12 schematically shown in FIG. 3. The underside 128 of the transverse circuit board section 12x is mechanically contacted with the fixation means 15, which is applied on the transverse surface 103x of the body element 103. The underside 128 of the longitudinal circuit board section 12y is mechanically contacted with the fixation means 15 which is applied on the longitudinal surface 103y of the body element 103. The underside 128 of the vertical circuit board section 12z is mechanically contacted with the fixation means 15 which is applied on the vertical surface 103z of the body element 103.

The first flexible section 12f is bent at a right angle and crosses the first edge 103xy to dispose the transverse circuit board section 12x at a right angle with respect to the longitudinal circuit board section 12y. The second flexible section 12f′ is bent at a right angle and crosses the second edge 103yz to dispose the vertical circuit board section 12z at a right angle with respect to the longitudinal circuit board section 12y. In the perspective view of FIG. 5, the second edge 103yz and the second flexible section 12f′ are hidden by other elements. The third flexible section 12f″ is bent at a right angle to dispose the longitudinal circuit board section 12y at a right angle with respect to the connector section 12c, and the connector section 12c reaches through the longitudinal housing opening 102y towards the outside of the housing element 10.

In step I, after completing the mechanical contact of the flexible printed circuit board element 12 with the applied fixation means 15, the fixation means 15 is cured to obtain the mechanical end strength of the adhesive bonding. The transverse circuit board section 12x is mechanically fixed to the transverse surface 103x, the longitudinal circuit board section 12y is mechanically fixed to the longitudinal surface 103y, and the vertical circuit board section 12z is mechanically fixed to the vertical surface 103z. The mechanical fixation is achieved via the applied fixation means 15. The mounting of the flexible printed circuit board element 12 in the housing element 10 is accomplished during this Step I.

### Step II

FIG. 6 is a disassembled perspective view during mounting of a portion of a plurality of measuring elements 11x, 11y, 11z of FIG. 2 in the housing element 10 of the piezoelectric acceleration sensor 1 of FIG. 5.

In step II, each of the measuring elements 11x, 11y, 11z is inserted into the inner space 101 of the housing element 10. In a tri-axial acceleration sensor, the transverse measuring element 11x is introduced via the transverse housing opening 102x in the inner space 101, the longitudinal measuring element 11y is introduced via the longitudinal housing opening 102y in the inner space 101, and the vertical measuring element 11z is introduced via the vertical housing opening 102z in the inner space 101.

In step II, the introduced measuring elements 11x, 11y, 11z are mechanically contacted with the body element 103. The transverse post surface 111yz of the transverse post 111x of the transverse measuring element 11x schematically shown in FIG. 2 is mechanically contacted with the related transverse surface 103x of the body element 103 schematically shown in FIG. 1. In the perspective view of FIG. 6, the transverse post surface 111yz is hidden by other elements. Due to the mechanical contact, the ground transverse face 113x− of the transverse measuring element 11x schematically shown in FIG. 2 is electrically connected with the housing element 10 such that the ground electric charge Cg of the transverse measuring element 11x is electrically conducted to the housing element 10. The longitudinal post surface 111zx of the longitudinal post 111y of the longitudinal measuring element 11y schematically shown in FIG. 2 is mechanically contacted with the related longitudinal surface 103y of the body element 103 schematically shown in FIG. 1. In the perspective view of FIG. 6, the longitudinal post surface 111zx and the longitudinal surface 103y are hidden by other elements. Due to the mechanical contact, the ground longitudinal face 113y− of the longitudinal measuring element 11y schematically shown in FIG. 2 is electrically connected with the housing element 10 such that the ground electric charge Cg of the longitudinal measuring element 11y is electrically conducted to the housing element 10. The vertical post surface 111xy of the vertical post 111z of the vertical measuring element 11z schematically shown in FIG. 2 is mechanically contacted with the related vertical surface 103z of the body element 103 schematically shown in FIG. 1. Due to the mechanical contact, the ground vertical face 113z− of the vertical measuring element 11z schematically shown in FIG. 2 is electrically connected with the housing element 10 such that the ground electric charge Cg of the vertical measuring element 11z is electrically conducted to the housing element 10.

As a result of the operations described above, in step II, the faces 113x−, 113y−, 113z− of the plurality of measuring elements 11x, 11y, 11z and the housing element 10 are electrically connected so as to possess the same electrical potential.

In step II, after completing the mechanical contacts of each of the measuring elements 11x, 11y, 11z with the body element 103, the mechanical contacts are mechanically fixed. The transverse measuring element 11x is mechanically fixed to the transverse surface 103x, the longitudinal measuring element 11y is mechanically fixed to the longitudinal surface 103y and the vertical measuring element 11z is mechanically fixed to the vertical surface 103z. This mechanical fixation is obtained by material bonding such as welding, soldering, adhesive bonding, etc. Preferably, this mechanical fixation is obtained by welding the post surfaces 111yz, 111zx, 111xy of the posts 111x, 111y, 111z of each of the measuring elements 11x, 11y, 11z to related surface 103x, 103y, 103z. Preferably, the welding occurs by resistance welding.

### Step III

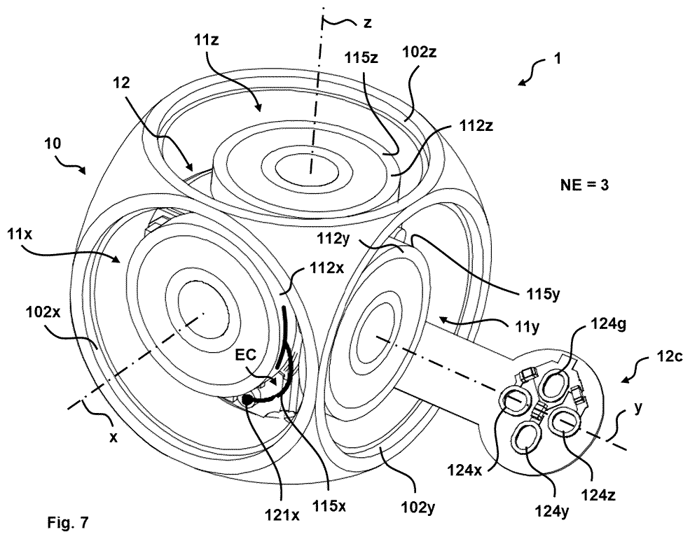

FIG. 7 is a perspective view that schematically shows a portion of first electrical connections EC of the plurality of measuring elements 11x, 11y, 11z with the flexible printed circuit element 12 of FIG. 6.

In step III, the plurality of measuring elements 11x, 11y, 11z is electrically connected with a connection site 121x, 121y, 121z, which is schematically shown in FIG. 4, of a related circuit board section 12x, 12y, 12z. For these first electrical connections EC, a plurality of measuring element wires 115x, 115y, 115z is provided as schematically shown in FIG. 4. As shown in FIG. 7 for example, the transverse measuring element 11x is electrically connected by means of a transverse measuring element wire 115x with a transverse connection site 121x of a related transverse circuit board section 12x, which is shown in FIG. 3. Preferably, the transverse measuring element wire 115x is electrically connected with the transverse preloading element 114x (depicted in FIG. 2) of the transverse measuring element 11x. Similarly, the longitudinal measuring element 11y is electrically connected by means of a longitudinal measuring element wire 115y with a longitudinal connection site 121y of a related longitudinal circuit board section 12y. Preferably, the longitudinal measuring element wire 115y is electrically connected with the longitudinal preloading element 114y of the longitudinal measuring element 11y. In the perspective view of FIG. 7, the longitudinal connection site 121y, the longitudinal measuring element wire 115y and the longitudinal preloading element 114y are hidden by other elements. The vertical measuring element 11z is electrically connected by means of a vertical measuring element wire 115z with a vertical connection site 121z of a related vertical circuit board section 12z. Preferably, the vertical measuring element wire 115z is electrically connected with the vertical preloading 114z of the vertical measuring element 11z. In the perspective view of FIG. 7, the vertical connection site 121z, the vertical measuring element wire 115z and the vertical preloading element 114z are hidden by other elements.

The number of first electrical connections NE of the plurality of measuring elements 11x, 11y, 11z with the plurality of circuit board sections 12x, 12y, 12z is equal to the number of the plurality of sensitive axes x, y, z. Preferably, for a number of the plurality of sensitive axes x, y, z, of three, the number of first electrical connections NE is three.

The plurality of measuring element wires 115x, 115y, 115z is made of electrically conductive material such as copper, copper alloys, etc. Preferably, the electrical connection EC of the plurality of measuring element wires 115x, 115y, 115z with the plurality of measuring elements 11x, 11y, 11z and the plurality of connection sites 121x, 121y, 121z is obtained by material bonding such as wire bonding, thermocompression bonding, thermosonic ball wedge bonding, ultrasonic wedge bonding, etc.

### Step IV

FIG. 8 is a perspective view of disassembled portions of the plurality of cover elements 13x, 13z and of the connector element 14 before being mounted to the housing element 10 of the piezoelectric acceleration sensor 1 of FIG. 7.

In step IV, the transverse cover element 13x is mounted on the transverse housing opening 102x of the housing element 10 such that the transverse housing opening 102x is closed by the transverse cover element 13x and the vertical cover element 13z is mounted on the vertical housing opening 102z of the housing element 10 such that the vertical housing opening 102z is closed by the vertical cover element 13z.

FIG. 9 is a perspective view of a portion of further electrical connections FEC of the flexible printed circuit element 12 of FIG. 7 with the connector element 14 of FIG. 8.

In step IV, in order to realize the further electrical connections FEC, the connector housing element 140 is placed outside the longitudinal housing opening 102y of the housing element 10 where the connector section 12c reaches through the longitudinal housing opening 102y towards the outside of the housing element 10. As schematically shown in FIG. 9, the plurality of connection areas 124x, 124y, 124z, 124g of the connector section 12c is mechanically contacted with the plurality of electric connector conductors 141x, 141y, 141z, 141g of the connector element 14. The transverse connection area 124x is mechanically contacted with the transverse electric connector conductor 141x 124x such that the transverse output voltage Ux is electrically conducted to the evaluation unit, which is disposed outside the housing element 10. The longitudinal connection area 124y is mechanically contacted with the longitudinal electric connector conductor 141y such that the longitudinal output voltage Uy is electrically conducted to the evaluation unit, which is outside the housing element 10. The vertical connection area 124z is mechanically contacted with the vertical electric connector conductor 141z such that the vertical output voltage Uz is electrically conducted to the evaluation unit, which is outside the housing element 10. The ground connection area 124g is mechanically contacted with the ground electric connector conductor 141g. such that the ground output voltage Ug is electrically conducted to the evaluation unit, which is outside the housing element 10.

In step IV, after completing the mechanical contacts of the plurality of connection areas 124x, 124y, 124z, 124g with the plurality of electric connector conductors 141x, 141y, 141z, 141g shown in FIGS. 4 and 9, the mechanical contacts are further electrically connected. These further electrical connections FEC are obtained by material bonding such as wire bonding, thermocompression bonding, thermosonic ball wedge bonding, ultrasonic wedge bonding, etc.

The number of further electrical connections NFE of the plurality of connection areas 124x, 124y, 124z, 124g with the plurality of electric connector conductors 141x, 141y, 141z, 141g is equal to the number of the plurality of output voltages Ux, Uy, Uz, Ug. Preferably, for a number of the plurality of output voltages Ux, Uy, Uz, Ug of four, the number of further electrical connections NFE is four.

In step IV, a ground housing wire 116g is provided as schematically shown in FIG. 4. The housing ground wire 116g is made of electrically conductive material such as copper, copper alloys, etc. An electrical ground connection EGC is completed by electrically connecting the connector housing element 140 by means of the ground housing wire 116g with the ground electric connector conductor 141g. Preferably, the electrical ground connection EGC is obtained by material bonding such as wire bonding, thermocompression bonding, thermosonic ball wedge bonding, ultrasonic wedge bonding, etc.

In step IV, once the further electrical connections FEC of the plurality of connection areas 124x, 124y, 124z, 124g with the plurality of electric connector conductors 141x, 141y, 141z, 141g is accomplished, and once the electrical ground connection EGC of the connector housing element 140 with the ground electric connector conductor 141g is accomplished, the connector section 12c is pushed through the vertical housing opening 102z into the inner space 101 of the housing element 10 and the connector housing element 140 is mounted on the vertical housing opening 102z such that the vertical housing opening 102z is closed by the connector housing element 140.

FIG. 10 is a perspective view of a portion of the plurality of cover elements 13x, 13y and the connector element 14 of FIG. 8 after being mounted in the housing element 10 of the piezoelectric acceleration sensor 1 of FIG. 8.

In step IV, the hermetic closure of the plurality of housing openings 102x, 102y, 102z is obtained by material bonding such as welding, soldering, adhesive bonding, etc. As shown in FIG. 10, the hermetic closure is preferably obtained by welding the mounted transverse cover element 13x to the transverse housing opening 102x shown in FIG. 1, by welding the mounted longitudinal cover element 103y to the longitudinal housing opening 102y shown in FIG. 1 and by welding the mounted connector housing element 140 to the vertical housing opening 102z shown in FIG. 1. The hermetic closure of the mounted plurality of housing openings 102x, 102y, 102z is accomplished.

As a consequence, in step IV, due to the welding of the mounted connector housing element 140 to the vertical housing opening 102z of the housing element 10, the connector housing element 140 and the housing element 10 possess the same electrical potential. Just as the housing element 10 and the faces 113x−, 113y−, 113z− of the plurality of measuring elements 11x, 11y, 11z possess the same electrical potential and just as the ground connector 121g, the ground electric conductor 127g, the ground connection area 124g and the ground electric connector conductor 141g possess the same electrical potential, as a consequence, the ground output voltage Ug is common to the housing element 10, the plurality of measuring elements 11x, 11y, 11z, the flexible printed circuit board element 12 and the connector element 14. Through it, the piezoelectric acceleration sensor 1, has no electrical potential differences.

While exemplary embodiments have been disclosed hereinabove, the present invention is not limited to the disclosed embodiments. Instead, the present invention covers any variations, uses, or adaptations of this disclosure using its general principles. Further, the present invention is intended to cover such departures from this disclosure as come within known or customary practice in the art to which the present invention pertains and which fall within the limits of the allowable claims.

Thus, the present invention is not limited to the embodiment of electrical ground connection EGC of the connector housing element 140 by means of the ground housing wire 116g with the ground electric connector conductor 141g. The person of ordinary skill in the art may realize a different kind of electrical ground connection between the housing element, the plurality of measuring elements, the flexible printed circuit board element and the connector element such as an electrical ground connection between the ground connector or the ground electric conductor of the flexible printed circuit board element with the housing element.

### LIST OF REFERENCE NUMERALS

1 piezoelectric acceleration sensor
10 housing element
10x, 10x′ transverse side face
10y, 10y′ longitudinal side face
10z, 10zł vertical side face
101 inner space
102x transverse housing opening
102y longitudinal housing opening
102z vertical housing opening
103 body element
103x transverse surface
103y longitudinal surface
103z vertical surface
103xy first edge
103yz second edge
103zx third edge
11x transverse measuring element
11y longitudinal measuring element
11z vertical measuring element
111x transverse post
111y longitudinal post
111z vertical post
111yz transverse post surface
111zx longitudinal post surface
111xy vertical post surface
112x transverse seismic mass
112y longitudinal seismic mass
112z vertical seismic mass
113x transverse piezoelectric element
113y longitudinal piezoelectric element
113z vertical piezoelectric element
113x+ transverse face
113x− ground transverse face
113y+ longitudinal face
113y− ground longitudinal face
113z+ vertical face
113z− ground vertical face
114x transverse preloading element
114y longitudinal preloading element
114z vertical preloading element
115x transverse measuring element wire
115y longitudinal measuring element wire
115z vertical measuring element wire
116g ground housing wire
12 flexible printed circuit board element
12c connector section
12d circuit board substrate surface
12d′ flexible substrate surface
12f, 12f′, 12f″ flexible section
12s circuit board substrate
12s flexible substrate
12x transverse circuit board section
12y longitudinal circuit board section
12z vertical circuit board section
121g ground connector
121x transverse connection site
121y longitudinal connection site
121z vertical connection site
122x transverse IEPE
122y longitudinal IEPE
122z vertical IEPE
123x transverse TEDS
123y longitudinal TEDS
123z vertical TEDS
124g ground connection area
124x transverse connection area
124y longitudinal connection area
124z vertical connection area
125x transverse electrostatic discharge protector
125y longitudinal electrostatic discharge protector
125z vertical electrostatic discharge protector
127g ground electric conductor
127x transverse electric conductor
127y longitudinal electric conductor
127z vertical electric conductor
128 underside
13x, 13z cover element
14 connector element
140 connector housing element
140′ connector housing through hole
141g ground electric connector conductor
141x transverse electric connector conductor
141y longitudinal electric connector conductor
141z vertical electric connector conductor
142 electric insulation element
Cx transverse electric charge
Cy longitudinal electric charge
Cz vertical electric charge
EC electrical connection
EGC electrical ground connection
FEC further electrical connection
Ix transverse Information
Iy longitudinal information
Iz vertical information
NE number of first electrical connections
NFE number of further electrical connections
Ug ground output voltage
Ux transverse output voltage
Uy longitudinal output voltage
Uz vertical output voltage
x transverse axis
y longitudinal axis
z vertical axis

What is claimed is:

1. A method of manufacturing a piezoelectric acceleration sensor that includes a housing element, a body element, a plurality of measuring elements, a connector element, and a flexible printed circuit board element that defines a plurality of circuit board sections, wherein the housing element defines an inner space in which the body element is disposed, wherein each of the plurality of measuring elements is configured to generate a respective measured acceleration along a respective one of a plurality of sensitive axes that are orthogonally related to each other, wherein each of the plurality of measuring elements is configured to create a respective one of a plurality of electric charges for the respective measured acceleration, wherein the flexible printed circuit board element hosts a plurality of IEPE, wherein each of the plurality of IEPE amplifies and converts electric charge from a related one of the plurality of measuring elements into a respective output voltage, wherein the flexible printed circuit board element establishes a ground output voltage; the method comprising:
configuring the flexible printed circuit board element into pre-shaped printed circuit board wherein each of the plurality of circuit board sections is disposed to lie generally in a respective plane that is orthogonal to a respective plane in which lies each other of the plurality of circuit board sections;
introducing the pre-shaped printed circuit board into the inner space of the housing element;
mechanically fixing the pre-shaped printed circuit board to the body element;
introducing the plurality of measuring elements into the inner space of the housing element and mechanically fixing each of the plurality of measuring elements to the body element;
electrically connecting each of the plurality of measuring elements with a respective one of the plurality of circuit board sections of the pre-shaped printed circuit board element via a respective one of a plurality of first electrical connections, wherein the number of first electrical connections is equal to the number of the plurality of sensitive axes;
electrically connecting the connector element with a connector section of the flexible printed circuit board via a respective one of a plurality of further electrical connections, wherein the number of further electrical connections is equal to the number of the plurality of output voltages; and
mounting the electrically connected connector element on the housing element.

2. The method according to claim 1, wherein the body element has a plurality of surfaces, including a transverse surface which is oriented normal to a transverse axis, a longitudinal surface which is oriented normal to a longitudinal axis and a vertical surface which is oriented normal to a vertical axis, the transverse axis, longitudinal axis and vertical axis are perpendicular to each other,
wherein the plurality of circuit board sections include a transverse circuit board section, a longitudinal circuit board section and a vertical circuit board section,
wherein the plurality of measuring elements includes a transverse measuring element which measures an acceleration along the transverse axis as sensitive axis, a longitudinal measuring element which measures an acceleration along the longitudinal axis as sensitive axis and a vertical measuring element which measures an acceleration along the vertical axis as sensitive axis,
wherein in the transverse circuit board section is mechanically fixed to the transverse surface, the longitudinal circuit board section is mechanically fixed to the longitudinal surface and a vertical circuit board section is mechanically fixed to the vertical surface.

3. The method according to claim 2, wherein the transverse measuring element is mechanically fixed to the transverse surface, the longitudinal measuring element is mechanically fixed to the longitudinal surface and the vertical measuring element is mechanically fixed to the vertical surface.

4. The method according to claim 1, wherein two of the plurality of surfaces are directly adjacent and are separated from each other by a common edge, including a first edge which separates the transverse surface from the longitudinal surface and a second edge which separates the longitudinal surface from the vertical surface,
wherein the flexible printed circuit board element comprises a connector section and a plurality of flexible sections, including a first flexible section which flexibly links the transverse circuit board section with the vertical circuit board section, a second flexible section which flexibly links the longitudinal circuit board section with the vertical circuit board section and a third flexible section which flexibly links the vertical circuit board section with the connector section,
wherein the first flexible section is bent and crosses the first edge and the second flexible section is bent and crosses the second edge.

5. The method according to claim 4, wherein the housing element comprises a plurality of housing openings, including a transverse housing opening to access the inner space from the direction of the transverse axis, a longitudinal housing opening to access the inner space from the direction of the longitudinal axis and a vertical housing opening to access the inner space from the direction of the vertical axis,
wherein the third flexible section is bent and the connector section reaches through the vertical housing opening towards the outside of the housing element; and
wherein in step II the transverse measuring element is introduced via the transverse housing opening in the inner space, the longitudinal measuring element is introduced via the longitudinal housing opening in the inner space and the vertical measuring element is introduced via the vertical housing opening in the inner space.

6. The method according to claim 2, wherein a fixation material is applied on the plurality of surfaces of the body element prior to the introduction of the flexible printed circuit board element in the inner space of the housing element; and
wherein each of the plurality of circuit board sections comprises an underside and the underside of the transverse circuit board section is mechanically contacted with the applied fixation material and mechanically fixed by adhesive bonding via the applied fixation material to the transverse surface, the underside of the longitudinal circuit board section is mechanically contacted with the applied fixation material and mechanically fixed by adhesive bonding via the applied fixation material to the longitudinal surface and the underside of the vertical circuit board section is mechanically contacted with the applied fixation material and mechanically fixed by adhesive bonding via the applied fixation material to the vertical surface.

7. The method according to claim 2, wherein each of the plurality of measuring elements comprises a post, a seismic mass and a piezoelectric element, the plurality of posts comprises a transverse post which mechanically supports a transverse seismic mass and a transverse piezoelectric element of the transverse measuring element and comprises a transverse post surface, a longitudinal post which mechanically supports a longitudinal seismic mass and a longitudinal piezoelectric element of the longitudinal measuring element and comprises a longitudinal post surface and a vertical post which mechanically supports a vertical seismic mass and a vertical piezoelectric element of the vertical measuring element and comprises a vertical post surface,
wherein the transverse post surface of the transverse measuring element is mechanically fixed by material bonding to the transverse surface, the longitudinal post surface of the longitudinal measuring element is mechanically fixed by material bonding to the longitudinal surface and the vertical post surface of the vertical measuring element is mechanically fixed by material bonding to the vertical surface.

8. The method according to claim 2, wherein each of the plurality of circuit board sections comprises a connection site, including a transverse connection site, a longitudinal connection site and a vertical connection site,
wherein a plurality of measuring element wires is provided, including a transverse measuring element wire, a longitudinal measuring element wire and a vertical measuring element wire,
wherein the first electrical connection of the transverse measuring element to a transverse connection site is made by a transverse measuring element wire, the first electrical connection of the longitudinal measuring element to the longitudinal connection site is made by a longitudinal measuring element wire and the first electrical connection of the vertical measuring element to the vertical connection site is realized by a vertical measuring element wire.

9. The method according to claim 7, wherein the plurality of piezoelectric elements comprise a plurality of ground faces, including a second transverse face, where ground electric charge is created for an acceleration, the ground transverse face is electrically connected with the transverse post, a ground longitudinal face, where ground electric charge is created for an acceleration, the ground longitudinal face is electrically connected with the longitudinal post and a ground vertical face, where ground electric charge is created for an acceleration, the ground vertical face is electrically connected with the vertical post,
wherein the mechanic fixation of the transverse measuring element to the transverse surface electrically connects the transverse post with the transverse surface, the mechanic fixation of the longitudinal measuring element to the longitudinal surface electrically connects the longitudinal post with the longitudinal surface, and the mechanic fixation of the vertical measuring element to the vertical surface electrically connects the vertical post with the vertical surface.

10. The method according to claim 8, wherein each of the plurality of circuit board sections comprises an IEPE, including a transverse IEPE on the transverse circuit board section, the transverse connection site is electrically connected to an IEPE input of the transverse IEPE, a longitudinal IEPE on the longitudinal circuit board section which amplifies and converts longitudinal electric charge from the longitudinal measuring element into a longitudinal output voltage, the longitudinal connection site is electrically connected to an IEPE input of the longitudinal IEPE and a vertical IEPE on the circuit board section which amplifies and converts vertical electric charge from the vertical measuring element into a vertical output voltage, the vertical connection site is electrically connected to an IEPE input of the vertical IEPE,
wherein the first electrical connection of the transverse measuring element to the transverse connection site electrically conducts transverse electric charge from the transverse measuring element to the transverse IEPE which amplifies and converts the transverse electric charge into a transverse output voltage, the first electrical connection of the longitudinal measuring element to the longitudinal connection site electrically conducts longitudinal electric charge from the longitudinal measuring element to the longitudinal IEPE which amplifies and converts the longitudinal electric charge into a longitudinal output voltage, and the first electrical connection of the vertical measuring element to the vertical connection site electrically conducts vertical electric charge from the vertical measuring element to the vertical IEPE which amplifies and converts the vertical electric charge into a vertical output voltage.

11. The method according to claim 2, wherein the connector element comprises a plurality of electric connector conductors, including a transversal electric connector conductor, a longitudinal electric connector conductor, a vertical electric connector conductor and a ground electric connector conductor,
wherein the connector section comprises a plurality of connection areas, including a transverse connection area, a longitudinal connection area, a vertical connection area and a ground connection area,
wherein the further electrical connection is realized between the transverse electric connector conductor and the transverse connection area, the further electrical connection is realized between the longitudinal electric connector conductor and the longitudinal connection area, the further electrical connection is realized between the vertical electric connector conductor and the vertical connection area and the further electrical connection is realized between the ground electric connector conductor and the ground connection area.

12. Method according to claim 11, wherein the connector element comprises a connector housing element and a ground housing wire is provided and an electrical ground connection is realized by electrically connecting the connector housing element by means of the ground housing wire with the ground electric connector conductor.

13. A piezoelectric acceleration sensor comprising:
a housing element defining an inner space;
a body element disposed within the inner space of the housing element and defining at least a first sensitive axis and a second sensitive axis, which extends in a direction that is normal to the first sensitive axis;
at least a first measuring element mechanically held by the body element and configured and disposed to generate a first electric charge proportional to a first acceleration acting along the first sensitive axis;
at least a second measuring element mechanically held by the body element and configured and disposed to generate a second electric charge proportional to a second acceleration acting along the second sensitive axis;
a flexible printed circuit board element mechanically fixed to the body element and configured and disposed to establish a ground output voltage;
wherein the flexible printed circuit board element defines a first circuit board section and a second circuit board section, wherein the first circuit board section is disposed to lie generally in a first plane, wherein the second circuit board section is disposed to lie generally in a second plane that is disposed orthogonally to the first plane so as to configure the flexible printed circuit board element into pre-shaped printed circuit board;
wherein the first circuit board section carries a first IEPE and a first electrical connection to the first measuring element, wherein the first IEPE is configured to amplify the first electric charge from the first measuring element and convert the amplified first electric charge into a first output voltage;
wherein the second circuit board section carries a second IEPE and a second electrical connection to the second measuring element, wherein the second IEPE is configured to amplify the second electric charge from the second measuring element and convert the amplified second electric charge into a second output voltage; and
a connector element;
wherein the flexible printed circuit board element includes a connector section and the connector element has a further electrical connection with the connector section.

14. The piezoelectric acceleration sensor according to claim 13, wherein the plurality of measuring elements includes a transverse measuring element that is configured to measure an acceleration along the transverse axis as the first sensitive axis, a longitudinal measuring element that is configured to measure an acceleration along the longitudinal axis as the second sensitive axis and a vertical measuring element that is configured to measure an acceleration along the vertical axis as a third sensitive axis;
wherein each of the plurality of circuit board sections comprises a connection site, including a transverse connection site, a longitudinal connection site and a vertical connection site; and
wherein the first electrical connection of the transverse measuring element to a transverse connection site, is realized by a transverse measuring element wire, the first electrical connection of the longitudinal measuring element to the longitudinal connection site is realized by a longitudinal measuring element wire and the first electrical connection of the vertical measuring element to the vertical connection site is realized by a vertical measuring element wire.

15. The piezoelectric acceleration sensor according to claim 13, wherein the connector element comprises a plurality of electric connector conductors, including a transversal electric connector conductor, a longitudinal electric connector conductor, a vertical electric connector conductor and a ground electric connector conductor,
wherein the connector section defines a plurality of connection areas, including a transverse connection area, a longitudinal connection area, a vertical connection area and a ground connection area,
wherein the further electrical connection is made between the transverse electric connector conductor and the transverse connection area, the further electrical connection is made between the longitudinal electric connector conductor and the longitudinal connection area, the further electrical connection is made between the vertical electric connector conductor and the vertical connection area and the further electrical connection is made between the ground electric connector conductor and the ground connection area.

16. The piezoelectric acceleration sensor according to claim 15, wherein the flexible printed circuit board element hosts a plurality of TEDS, the plurality of TEDS includes a transverse TEDS which stores transverse information about the first transverse measuring element, a longitudinal TEDS which stores longitudinal information about the second measuring element and a vertical TEDS which stores vertical information about the vertical measuring element; and
wherein the transverse electric connector conductor is configured to electrically conduct the transverse information, the longitudinal electric connector conductor is configured to electrically conduct the longitudinal information, and the vertical electric connector conductor is configured to electrically conduct the vertical information.

17. The piezoelectric acceleration sensor according to claim 13, further comprising a ground housing wire, wherein the connector element includes a connector housing element and the ground housing wire electrically connects the connector housing element with the ground electric connector conductor.

18. The piezoelectric acceleration sensor according to claim 13, further comprising a vertical measuring element connected to a vertical IEPE, which is configured to amplify and convert vertical electric charge from the vertical measuring element into a vertical output voltage;
wherein the plurality of IEPS includes a transverse IEPE which is configured to amplify and convert transverse electric charge from the first measuring element into a transverse output voltage, a longitudinal IEPE which is configured to amplify and convert longitudinal electric charge from the second measuring element into a longitudinal output voltage;
wherein the connector element comprises a plurality of electric connector conductors, including a transversal electric connector conductor, a longitudinal electric connector conductor, a vertical electric connector conductor and a ground electric connector conductor;
wherein the connector section defines a plurality of connection areas, including a transverse connection area, a longitudinal connection area, a vertical connection area and a ground connection area;
wherein the further electrical connection is made between the transverse electric connector conductor and the transverse connection area, the further electrical connection is made between the longitudinal electric connector conductor and the longitudinal connection area, the further electrical connection is made between the vertical electric connector conductor and the vertical connection area and the further electrical connection is made between the ground electric connector conductor and the ground connection area; and
wherein the transverse electric connector conductor is configured to electrically conduct the transverse output voltage, the longitudinal electric connector conductor is configured to electrically conduct the longitudinal output voltage, the vertical electric connector conductor is configured to electrically conduct the vertical output voltage, and the ground electric connector conductor is configured to electrically conduct the ground output voltage.

19. The piezoelectric acceleration sensor according to claim 13, wherein the housing element and the body element are defined as a unitary workpiece.
